(19) United States
(12) Patent Application Publication
(10) Pub. No.: US 2007/0074897 A1
(43) Pub. Date: Apr. 5, 2007

(54) Thermal event detection on printed wire boards

(76) Inventor: Ronald Lashley, Austin, TX (US)

Correspondence Address: HAMILTON & TERRILE, LLP, P.O. BOX 203518, AUSTIN, TX, 78720, US

(21) Appl. No.: 11/222,310

(22) Filed: Sep. 8, 2005

(51) Int. Cl. H05K 1/16

(52) U.S. Cl. 174/260

(57) ABSTRACT

The present invention provides a system and method for detecting thermal events on circuit boards, such as those used in information handling systems. In embodiments of the present invention, a plurality of thermal event detector traces are etched on a printed wire board (PWB) and are isolated from voltage planes in the PWB. In various embodiments of the invention, the thermal event detector traces comprise a pad or trace in a location under or near a component in a critical area. The thermal detection traces or pads are coupled to a detection circuit so that a thermal event resulting in thermal deformation or charring of the PWB in the area of these traces will trigger a power supply shutdown.

### BACKGROUND OF THE INVENTION

1. Field of the Invention

The present invention relates generally to circuit boards used in information handling systems. More specifically, the present invention provides an improved method and apparatus for monitoring information system circuit boards and for detecting defects related to charring of such circuit boards related to thermal events.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use, such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems typically comprise a plurality of circuit boards referred to as printed circuit boards (PCB) or printed wire boards (PWB). PWB boards typically comprise a plurality of conductive traces for providing electrical connections between components on the PWB. The traces are disposed in a plurality of layers in the PWB. In addition, power and ground signals are provided by appropriate ground planes and power planes disposed in the various layers of the PWB.

The electrical conductor traces in a PWB are delicate and can be damaged by fires or significant thermal events. Fires can occur in systems due to shorts by components, misaligned card edges, or layer to layer PWB shorts. The most difficult to detect are shorts to voltage planes that provide high current, especially the main power distribution voltage on a planar. The difference between normal load resistance and a burning PWB generally cannot be detected. Systems that are capable of consuming several hundred amps of current at various voltages make it difficult to detect small changes in current related to fires or thermal events. Once a fire starts, it propagates with power supply energy over an area of the PWB, producing fire and smoke that can shut down an information handling system and cause severe problems for the user. Smoke detection is complicated to design and is subject to false positive alarms from smoke or dust in the air intake of the information handling system.

### SUMMARY OF THE INVENTION

The present invention overcomes the shortcomings of the prior art by providing a plurality of thermal detection traces that are contained within a PWB. The thermal event detector traces are etched in the interior of the PWB and are isolated from voltage planes in the PWB. In various embodiments of the invention, the thermal event detector traces comprise a pad or trace in a location under or near a component in a critical area. The thermal detection traces or pads are coupled to a detection circuit so that a fire or charring of the PWB in the area of these traces will trigger a power supply shutdown.

In one embodiment of the invention, the fire detection traces are in series and are activated by generating an open circuit when exposed to excessive heat. The open circuit causes a detection circuit to trigger an appropriate alarm. In an alternate embodiment of the invention, the fire detector traces are disposed in parallel (electrical parallel) and are connected to ground via a high resistance value. Charring of the PCB in the area of any trace will connect the trace to the voltage plane via the conduction path created by the charred area and will pull the trace to a higher voltage. A detector circuit is operable to detect the higher voltage and to trigger an appropriate alarm. In another embodiment of the invention, the thermal event detector traces are disposed in different planes and are, therefore, arranged to make it possible for current in conductive signal traces to flow more readily in all directions over the voltage plane of the PWB.

In alternate embodiments of the invention, the traces are replaced with a simple pad located under, or in proximity to, a critical component such as a high-side FET for the CPU DC-DC converter (VRD).

All of the aforementioned embodiments of the invention require only a small amount of PWB area within the voltage plane or a PWB pad and, therefore, no additional PWB area is required.

The method and apparatus of the present invention detects an exothermal event on the voltage plane or critical component that cannot be detected by other methods such as over-current protection. The cost of implementing the present invention is inherently low since it uses the existing PWB and adds only a few logic or comparator devices to implement the detection circuitry.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 is a general illustration of components of an information handling system in accordance with the present invention.

FIG. 2 is a general illustration of a main system board comprising a plurality of circuit traces and a plurality of fire detector traces in accordance with an embodiment of the present invention.

FIG. 3 is an illustration of an embodiment of the present invention wherein a plurality of fire detector traces are disposed in a series connection.

FIG. 3a is an illustration of a portion of a PWB affected by a thermal event.

FIG. 4 illustrates an embodiment of the present invention wherein a plurality of fire detection traces are disposed in an electrically parallel connection.

FIG. 5 is an illustration of an embodiment of the invention wherein the fire detection traces are disposed in different planes of the PWB with appropriate interconnects to allow electrical signal conductors to be routed in all directions within a PWB.

FIG. 6 is an illustration of an alternate embodiment of the present invention wherein a plurality of fire detection pads are disposed on a printed wire board at predetermined locations to detect failure of a predetermined circuit component.

FIG. 6 is an illustration of an embodiment of the present invention wherein a fire detection pad is located in close proximity to a critical component.

### DETAILED DESCRIPTION

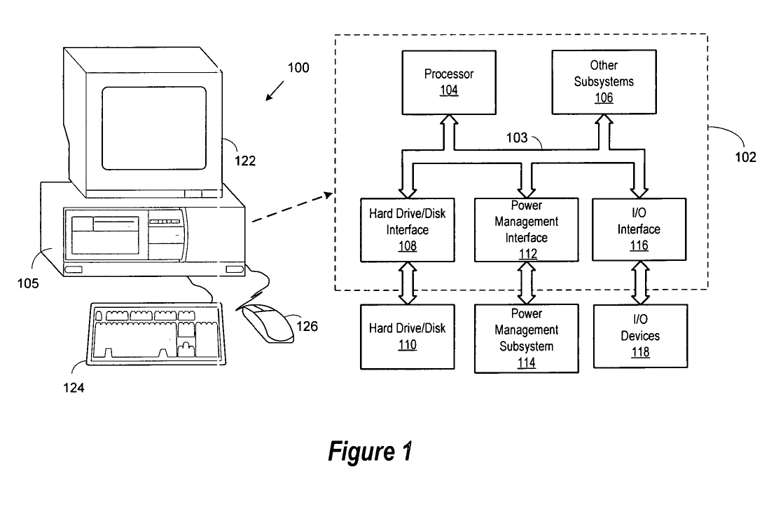

The method and apparatus of the present invention provides significant improvements in the manufacture and use of circuit boards such as those used in an information handling system 100 shown in FIG. 1. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

Referring to FIG. 1, the information handling system 100 includes a main system board 102 that comprises a processor 104 and various other subsystems 106 understood by those skilled in the art. Data is transferred between the various system components via various data buses illustrated generally by bus 103. A hard drive 110 is controlled by a hard drive/disk interface 108 that is operably connected to the hard drive/disk 110. An input/output (I/O) interface 116 controls the transfer of data between the various system components and a plurality of input/output (I/O) devices 118, such as a display 122, a keyboard 124, and a mouse 126. A power management interface 112 is operable to control a power management subsystem 114 that monitors and manages operation of a power supply, as discussed in greater detail hereinbelow. The main system board 102 and associated components are mounted in a housing 105 that may include one or more fans for cooling the system components.

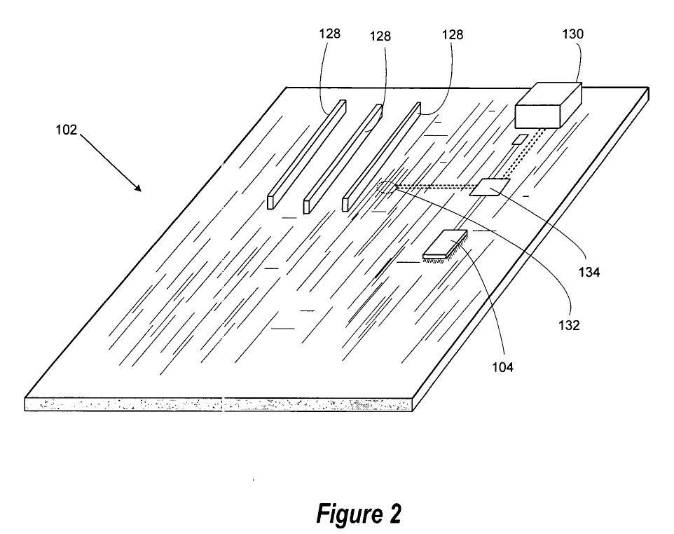

FIG. 2 is a generalized illustration of a printed wire board (PWB) such as the main system board (or motherboard) 102 discussed above in connection with FIG. 1. The PWB 102 comprises a plurality of expansion card slots 128 that can connect expansion circuit boards to enhance the functionality of the information handling system. As will be discussed in greater detail hereinbelow, the present invention provides a method and system for detecting thermal events that may cause damage to the PWB 102 and associated components. The PWB 102 comprises a plurality of thermal event detector traces 132 that are used by a power management subsystem 134 to control operation of the power supply 130 in the event of a thermal event such as a system board fire. The thermal event detector traces 132 are etched in the interior of the PWB 102 and are isolated from voltage planes in the PWB. The power management subsystem 134 is embodied in an integrated circuit that is operably coupled to the processor 104 and is operable to receive and execute data signals received by the processor to control operation of the power supply 130.

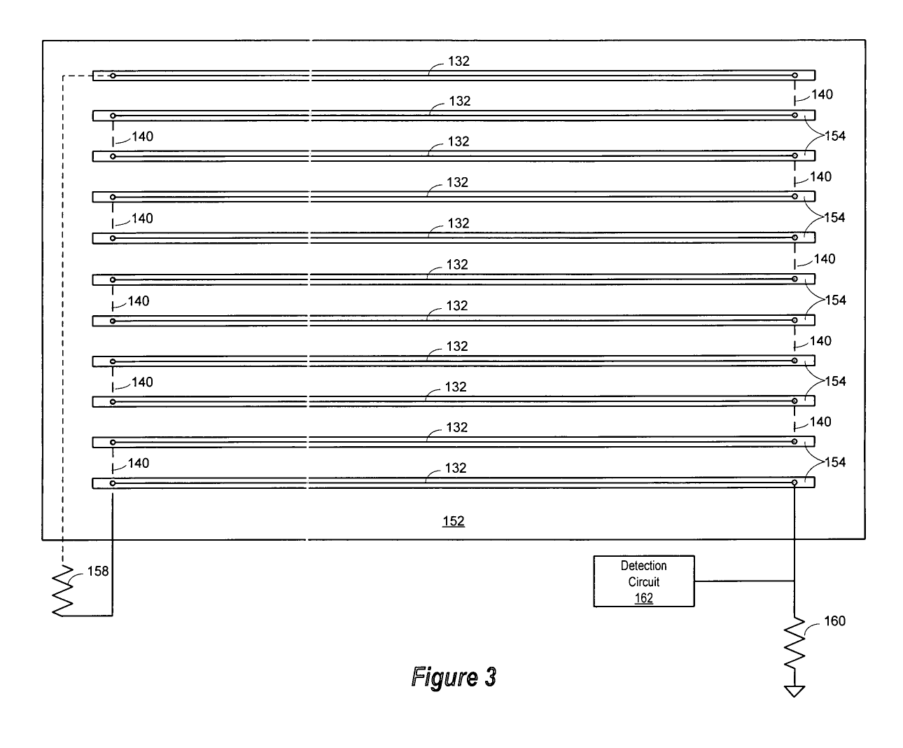

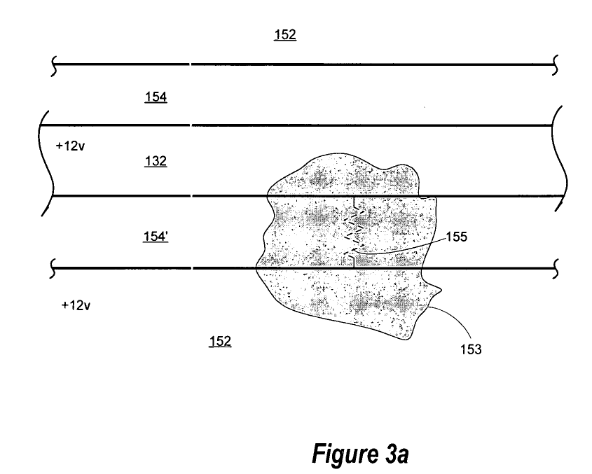

FIG. 3 illustrates an embodiment of the present invention wherein a plurality of thermal event detectors 132 are disposed in a first plane of the PWB 102 and are connected in a series configuration by a plurality of internal connector traces 140 disposed in a second plane of the PWB 102. The first plane of the PWB 102 also comprises a voltage plane 152 that is isolated from the various thermal event detection traces 132 by a plurality of “keep away” isolation areas 154. The voltage plane 152 is connected to the plurality of thermal event detectors 132 by a first resistor 158 and a second resistor 160 that is also connected to an appropriate ground connection. The resistors 158 and 160 are configured in a voltage divider arrangement with a detection circuit 162 connected to the second resistor 160. Under normal operating conditions, the keep away area 154 provides electrical isolation between the thermal event detectors and the power plane 152. If a thermal event occurs, there will be a change in the conductivity of a portion 153 of the isolation area between the thermal event detectors 132 and the power plane 152. The change in conductivity of the portion of the keep away area in the vicinity of the thermal event will result in increased conductivity that provides an electrical connection between the thermal event detector 132 and the power plane 152. This change of voltage is detected by detection circuit 162 which generates an appropriate output signal for use by the power management subsystem 134 to provide a rapid shutdown of the power supply 130.

FIG. 3a provides additional detail regarding the portion 153 of the isolation area 154 that is affected by a thermal event. Under normal operating conditions, the power plane 152 is at a positive potential, e.g. +12v. In the configuration illustrated in FIG. 3, the thermal event sensors are connected to the positive potential via the resistor 158. The thermal event detectors 132 are isolated from the power plane 152 by the isolation areas 154 that effectively have zero conductivity. A thermal event will result in the carbonization of a portion 153 of one or more of the isolation areas 154 that will result in the creation of an electrical pathway illustrated generally by resistor 155 in FIG. 3A. Each of the various embodiments of the invention discussed herein below are based on similar electrical pathways being formed in proximity to the thermal event detectors, although these areas will not be explicitly shown.

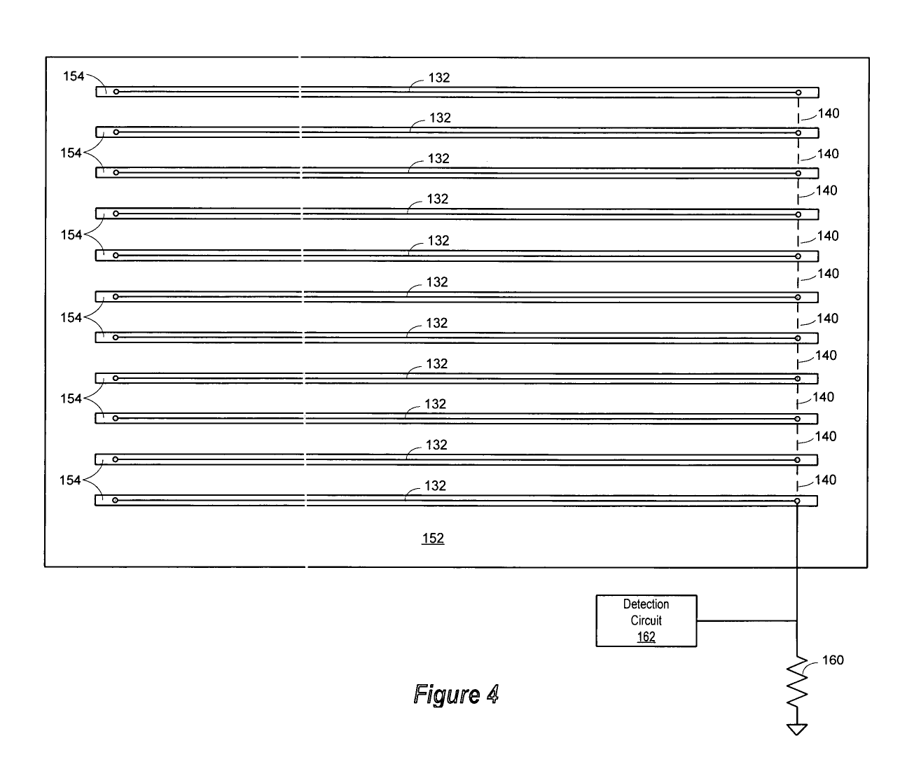

FIG. 4 is an illustration of an alternate embodiment of the present invention wherein a plurality of thermal event detectors 132 are connected in a parallel configuration. The thermal event detectors 132 connected to a resistor 160 that is connected to ground. The thermal event detectors 132 are isolated from the voltage plane by a plurality of isolation areas 154 and, therefore, in input to the detection circuit is normally “low.” If a thermal event occurs, there will be a change in the conductivity of the isolation area between the thermal event detectors 132 and the power plane 152, thereby creating an electrical connection between the power plane 152 and at least one of the detectors 132. The input to the detector circuit 162 will be pulled “high,” thereby causing the detection circuit to generate an appropriate thermal event output signal for use by the power management subsystem 134 to generate a control signal to cause a rapid shutdown of the power supply 130.

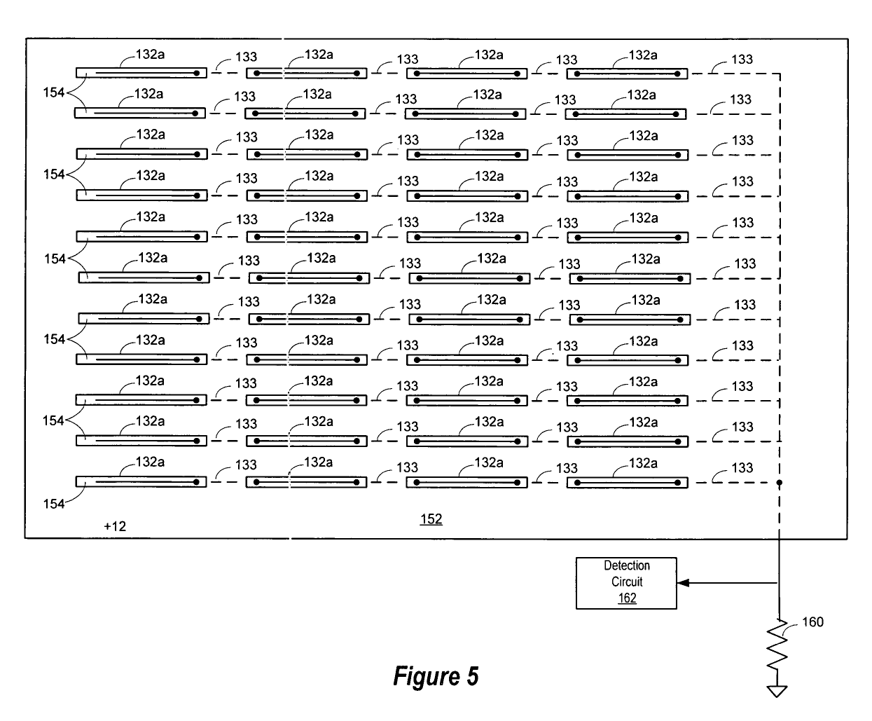

FIG. 5 is an illustration of an embodiment of the present invention wherein a plurality of thermal event detector segments 132a and 133 are connected to form a plurality of thermal event detectors in a parallel configuration. The segments 132a are disposed in a first plane of the PWB 102 and segments 133 are disposed in a second plane with a plurality of vias connecting segments 132a and 133 to form thermal event detectors. The areas between the detector segments 132a on the first plane of the PWB 102 can be used to route signal conductors in a perpendicular direction with respect to the individual traces 132a. This provides increased flexibility and efficiency in the layout of other circuit traces in the vicinity of the thermal event detector traces.

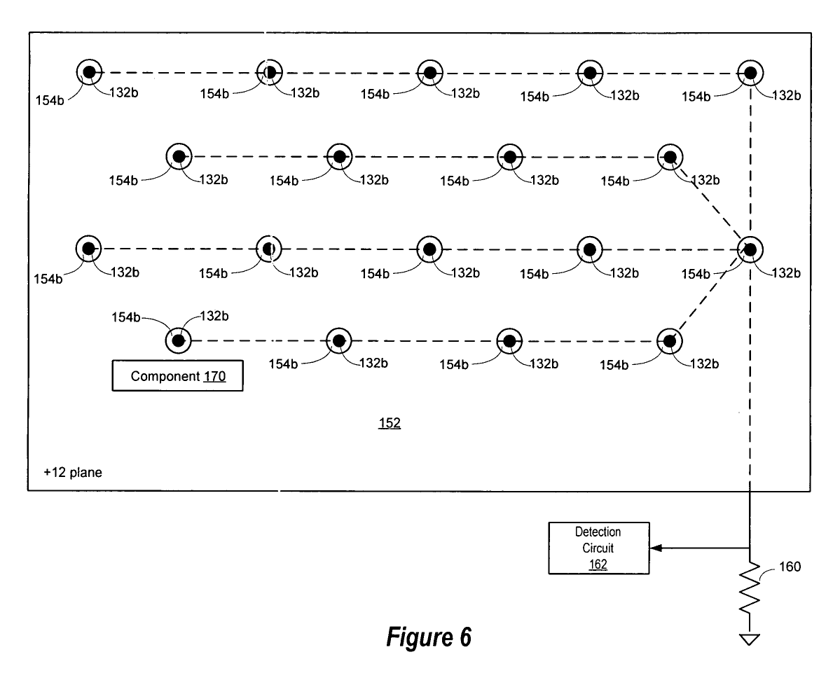

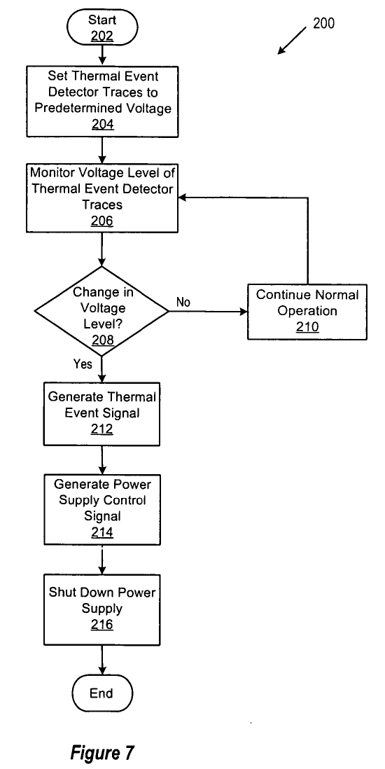

FIG. 6 is an illustration an embodiment of the invention wherein a plurality of thermal event detector pads are disposed at predetermined locations on a PWB. The detector pads 132b are placed at predetermined locations of particular interest for thermal monitoring. For example, a detector 132b can be located in proximity to a component 170 of particular interest. For example the thermal event detector pad can be placed near a critical component such as a high-side FET for the CPU DC-DC converter (VRD). Each of the detection pads 132b is isolated from the voltage plane 152 by an isolation area 154b. In the embodiment illustrated in FIG. 6, the detector pads 132b are connected to a resistor 160 that is connected to ground and, therefore, the input to the detector circuit 162 is normally “low.” An exothermic event associated with the component 170 will cause a change in the conductivity of the isolation area 154b thereby creating a conductive path between the voltage plane 152, or critical component voltage connection, and the detection pad 132b. The input to the detector circuit 162 will be pulled “high,” thereby causing the detection circuit to generate an appropriate thermal event output signal for use by the power management subsystem 134 to generate a control signal to cause a rapid shutdown of the power supply 130.

FIG. 7 is a flowchart illustration of the processing steps implemented in the present invention. In step 202, processing is initiated. In step 204, the thermal event detector traces 132 are set to a predetermined voltage corresponding to a first voltage state. In step 206, the voltage level of the thermal event detector traces 132 are monitored. In step 208, the test is conducted to determine if there has been a change in the voltage level of the thermal event detector traces 132 corresponding to a shift from a first voltage state to a second voltage state. If the results of the test conducted in step 208 indicates that there has been no change in voltage levels, processing proceeds to step 210 and normal operation of the system continues. If, however, the test conducted in step 208 indicates that there has been a change in any of the voltage level of the thermal event detector traces 132, processing proceeds to step 212 where a thermal event signal is generated. In step 214, a power supply control signal is generated to cause the power supply to shut down in step 216.

The present invention offers a significant improvement over prior methods for managing an information handling system power supply during a fire or significant thermal event. In particular, the present invention is capable of detecting an exothermic event on a PWB that cannot be detected by other methods such as over-current protection. The cost of implementing the present invention is inherently low since it uses the existing PWB and the detection circuitry can be implemented using only a few logic or comparator devices.

Although the present invention has been described in detail, it should be understood that various changes, substitutions and alterations can be made hereto without departing from the spirit and scope of the invention as defined by the appended claims.

1. A circuit board, comprising:
a plurality of thermal event detector conductor traces disposed on said circuit board and maintained at a first voltage state during normal operation of said circuit board;
a thermal event detector operable to detect a change in the voltage state of at least one of said thermal event detectors from said first voltage state to a second voltage state and to generate a thermal event detection signal in response to said change in voltage state;
a power management system operable to terminate the supply of power to said circuit board in response to said thermal event detection signal.

2. The circuit board according to claim 1, wherein said plurality of thermal event detectors are isolated from a voltage plane by a plurality of isolation regions during normal operation of said circuit board.

3. The circuit board according to claim 2, wherein said plurality of thermal event detectors are connected in a serial configuration.

4. The circuit board according to claim 2, wherein said plurality of thermal event detectors are connected in a parallel configuration.

5. The circuit board according to claim 4, wherein:
said circuit board comprises a plurality of planes; and
at least one of said thermal event detector comprises a first plurality of thermal event detector segments on a first plane and a second plurality of thermal event detectors on a second plane.

6. A method of detecting a thermal event on a circuit board, comprising:
placing a plurality of thermal event detectors on said circuit board;
maintaining said thermal event detectors at a first voltage state during normal operation of said circuit board;
detecting a change in the voltage state of at least one of said thermal event detectors from said first voltage state to a second voltage state;
generating a thermal event detection signal in response to said change in voltage state;
using a power management system to terminate the supply of power to said circuit board in response to said thermal event detection signal.

7. The method according to claim 1, wherein said plurality of thermal event detectors are isolated from a voltage plane by a plurality of isolation regions during normal operation of said circuit board.

8. The method according to claim 7, wherein said plurality of thermal event detectors are connected in a serial configuration.

9. The method according to claim 7, wherein said plurality of thermal event detectors are connected in a parallel configuration.

10. The method according to claim 9, wherein:
said circuit board comprises a plurality of planes;
and at least one of said thermal event detector comprises a first plurality of thermal event detector segments on a first plane and a second plurality of thermal event detectors on a second plane.

11. An information handling system, comprising:
at least one circuit board comprising information processing circuits and a plurality of signal conductors, said circuit board further comprising:
a plurality of thermal event detector conductor traces disposed on said circuit board and maintained at a first voltage state during normal operation of said circuit board;
a thermal event detector operable to detect a change in the voltage state of at least one of said thermal event detectors from said first voltage state to a second voltage state and to generate a thermal event detection signal in response to said change in voltage state;
a power management system operable to terminate the supply of power to said circuit board in response to said thermal event detection signal.

12. The information handling system according to claim 11, wherein said plurality of thermal event detectors are isolated from a voltage plane by a plurality of isolation regions during normal operation of said circuit board.

13. The information handling system according to claim 12, wherein said plurality of thermal event detectors are connected in a serial configuration.

14. The information handling system according to claim 12, wherein said plurality of thermal event detectors are connected in a parallel configuration.

15. The information handling system according to claim 14, wherein:
said circuit board comprises a plurality of planes; and
at least one of said thermal event detector comprises a first plurality of thermal event detector segments on a first plane and a second plurality of thermal event detector segments on a second plane.

16. A method of managing power in an information handling system by detecting thermal events, said information handling system including a circuit board comprising information processing circuits and a plurality of signal conductors, said method comprising:
placing a plurality of thermal event detectors on said circuit board;
maintaining said thermal event detectors at a first voltage state during normal operation of said circuit board;
detecting a change in the voltage state of at least one of said thermal event detectors from said first voltage state to a second voltage state;
generating a thermal event detection signal in response to said change in voltage state;
using a power management system to terminate the supply of power to said circuit board in response to said thermal event detection signal.

17. The method according to claim 16, wherein said plurality of thermal event detectors are isolated from a voltage plane by a plurality of isolation regions during normal operation of said circuit board.

18. The method according to claim 17, wherein said plurality of thermal event detectors are connected in a serial configuration.

19. The method according to claim 17, wherein said plurality of thermal event detectors are connected in a parallel configuration.

20. The method according to claim 19, wherein:
said circuit board comprises a plurality of planes;
and at least one of said thermal event detector comprises a first plurality of thermal event detector segments on a first plane and a second plurality of thermal event detectors on a second plane.
